(19) United States
(12) Patent Application Publication
(10) Pub. No.: US 2024/0319228 A1
(43) Pub. Date: Sep. 26, 2024

(54) PROBE MEMBER FOR INSPECTION, AND MANUFACTURING METHOD THEREFOR

(71) Applicant: Jung Gyun BAEK, Daegu (KR)

(72) Inventor: Jung Gyun BAEK, Daegu (KR)

(21) Appl. No.: 18/574,132

(22) PCT Filed: Jun. 28, 2022
(86) PCT No.: PCT/KR2022/009229

§ 371 Date: Dec. 26, 2023

(30) Foreign Application Priority Data
Jun. 28, 2021 (KR) 10-2021-0083969
Jun. 24, 2022 (KR) 10-2022-0077821

(51) Int. Cl. G01R 1/067; G01R 3/00

(52) U.S. Cl. CPC G01R 1/06738; G01R 1/06761; G01R 3/00

(57) ABSTRACT

A probe member for inspection according to an exemplary embodiment includes: a contact portion formed of a first metal with a sharp point on one side to contact an object to be inspected and a body portion formed of a second metal on the other side of the contact portion, wherein the body portion includes a concave portion formed on a side and having a second diameter smaller than a first diameter of the contact portion, and the contact portion and the body portion are formed through a separate process to form a boundary surface therebetween.

### TECHNICAL FIELD

The present invention relates to a probe member for inspection and a method for manufacturing the same, and more specifically, to a probe member for inspection having improved durability by reducing the number of boundary surfaces and a method for manufacturing the same.

### BACKGROUND ART

After a semiconductor device is completed, an electrical inspection is performed to confirm a normal operation or reliability. For the electrical inspection, a test device including a pad and a test socket are used.

The test socket connects a terminal of a semiconductor device to a pad of the test device, and the terminal of the semiconductor device and the test device may exchange electrical signals by the test socket.

To this end, a pogo pin is located as a contact unit inside the test socket.

The pogo pin, which includes a probe member and an elastic member, may facilitate contact between the semiconductor device and the test device and buffer mechanical shock that may occur during contact, and thus, the pogo pin is used in many test sockets.

The probe member has a boundary surface formed between processes depending on a structure and manufacturing method, and the boundary surface may reduce durability, when it is cut during use.

Therefore, as the number of boundary surfaces increases, durability may further deteriorate.

### DISCLOSURE

### Technical Problem

The present invention attempts to provide a probe member for inspection capable of improving durability by reducing the number of boundary surfaces. Another object of the present invention is to provide a method of manufacturing a probe member for inspection.

### Technical Solution

In an exemplary embodiment, a method of manufacturing a probe member for inspection includes: a first operation of forming a first layer mold in a first pattern on an upper surface of a substrate to be spaced apart from a groove formed on the upper surface of the substrate; a second operation of forming a contact portion by plating an inner surface of the first layer mold and a surface of the groove with a first metal; a third operation of forming a second layer mold in a second pattern on the contact portion and the first layer mold and forming a third layer mold in a third pattern on the second layer mold; a fourth operation of plating an internal space of the contact portion, the first layer mold, the second layer mold, and the third layer mold with a second metal to be filled with a boundary surface along a surface of the contact portion to form a body portion; and a fifth operation of removing the first layer mold, the second layer mold, the third layer mold, and the substrate to obtain a probe member.

In the third operation, centers of the first layer mold, the second layer mold, and the third layer mold may be aligned with a center of the contact portion, and a second pattern inner diameter of the second layer mold may be formed to be less than a first pattern inner diameter of the first layer mold and a third pattern inner diameter of the third layer mold, and in the fourth operation, a concave portion may be formed on a side of the body portion.

In the second operation, the contact portion may be formed to have a set thickness along the inner surface of the first layer mold and a shape of the groove.

In the fourth operation, the body portion may be formed by forming the boundary surface along an inner surface of the contact portion and filling the internal space.

In the first operation, the first layer mold may be formed on the upper surface of the substrate and further extend to be spaced over the groove.

In the second operation, the contact portion may be formed to fill a lower surface and the inner surface of the first layer mold and the groove to have a width narrower than an upper end of the groove and have a protrusion protruding to be higher than an upper surface of the substrate, and the first layer mold outside the contact portion may be removed to allow the protrusion to protrude from the upper surface of the substrate.

In the third operation, the first layer mold is formed again on the upper surface of the substrate to be spaced apart from the protrusion, the second layer mold may be formed in the second pattern on the protrusion and the first layer mold, and the third layer mold may be formed in the third pattern on the second layer mold.

In the fourth operation, the internal space of the contact portion, the protrusion, the first layer mold, the second layer mold, and the third layer mold may be plated with the second metal to form the body portion filling the internal space with the boundary surface along the surface of the contact portion and the protrusion.

In the second operation, the contact portion filling the inner surface of the first layer mold and the groove to have an expansion having a width greater than an upper end of the groove and protruding to be higher than the upper surface of the substrate may be formed.

In the third operation, the second layer mold may be formed in the second pattern on the first layer mold and extends on the expansion, and the third layer mold may be formed in the third pattern on the second layer mold, and in the fourth operation, the internal space of the expansion, the second layer mold, and the third layer mold may be plated with the second metal and filled with a boundary surface along a surface of the expansion to form the body portion.

In the second operation, a first boundary surface may be formed along the inner surface of the contact portion and plating may be performed with the second metal up to a height of the contact portion to form a first body portion, and in the fourth operation, a second boundary surface may be formed along an upper surface of the first body portion and plating may be performed with a third metal up to a height of the second layer mold and the third layer mold to form a second body portion.

In the third operation, an additional layer mold may be further formed in an additional pattern on the first layer mold and extends over the expansion, the second layer mold in the second pattern may be formed on the additional layer mold, and the third layer mold in the third pattern may be formed on the second layer mold, and in the fourth operation, the internal space of the expansion, the additional layer mold, the second layer mold, and the third layer mold may be plated with the second metal and filled with a boundary surface along a surface of the expansion to form a body portion having the additional layer.

In the first operation, the first layer mold in the first pattern may be formed on the upper surface of the substrate and spaced apart from a plurality of grooves formed on the upper surface of the substrate.

In another exemplary embodiment, a probe member for inspection includes: a contact portion formed of a first metal with a sharp point on one side to contact an object to be inspected; and a body portion formed of a second metal on the other side of the contact portion, wherein the body portion includes a concave portion or a convex portion formed on a side and having a second diameter smaller or greater than the first diameter of the contact portion, and the contact portion and the body portion may be formed through a separate process to form a boundary surface therebetween.

The contact portion may form an internal space connected to a container space having a height of a sharp pyramidal space on the other side, and the contact portion and the body portion may form a boundary surface along inner surfaces of the pyramidal space and the container space therebetween.

The contact portion may be filled in the groove and have a protrusion having a narrower width than an upper end of the groove and protruding higher than the upper end of the groove, and the body portion may form a boundary surface along surfaces of the contact portion and the protrusion therebetween.

The contact portion may be filled in the groove and have an expansion having a wider width than an upper end of the groove and protruding higher than the upper end of the groove, and the expansion and the body portion may form a boundary surface therebetween along the surface of the expansion.

The body portion may include a first body portion and a second body portion, the first body portion may form a first boundary surface along the inner surface of the contact portion and is formed up to a height of the contact portion, and the second body portion may form a second boundary surface along an upper surface of the first body portion.

The body portion may further include an additional layer on the expansion side, and the additional layer may form a boundary surface along a surface of the expansion therebetween.

The contact portion may be formed in plurality.

### Advantageous Effects

The probe member for inspection according to an exemplary embodiment may improve durability by forming one or two boundary surfaces to reduce the number of boundary surfaces. Therefore, since the number of boundary surfaces is reduced, the risk of separation from the boundary surface during use may be lowered and the number of unit operations in the manufacturing method and the resulting costs and time may be reduced.

### DESCRIPTION OF THE DRAWINGS

FIG. 1 is a flowchart illustrating cross-sections of a probe member for inspection and a manufacturing method thereof according to a first exemplary embodiment of the present invention.

FIG. 2 is a flowchart illustrating cross-sections of a probe member for inspection and a manufacturing method thereof according to a second exemplary embodiment of the present invention.

FIG. 3 is a flowchart illustrating cross-sections of a probe member for inspection and a manufacturing method thereof according to a third exemplary embodiment of the present invention.

FIG. 4 is a flowchart illustrating cross-sections of a probe member for inspection and a manufacturing method thereof according to a fourth exemplary embodiment of the present invention.

FIG. 5 is a cross-sectional view of a probe member for inspection according to a fifth exemplary embodiment of the present invention.

FIG. 6 is a cross-sectional view of a probe member for inspection according to a sixth exemplary embodiment of the present invention.

### MODE FOR INVENTION

Hereinafter, the present invention will be described more fully hereinafter with reference to the accompanying drawings, in which exemplary embodiments of the invention are shown. As those skilled in the art would realize, the described exemplary embodiments may be modified in various different ways, all without departing from the spirit or scope of the present invention.

In the drawings, parts irrelevant to the description are omitted to clearly describe the present invention, and like reference numerals denote like elements throughout the specification. To prevent duplication of description, a manufacturing method and a probe member manufactured using the manufacturing method are described together.

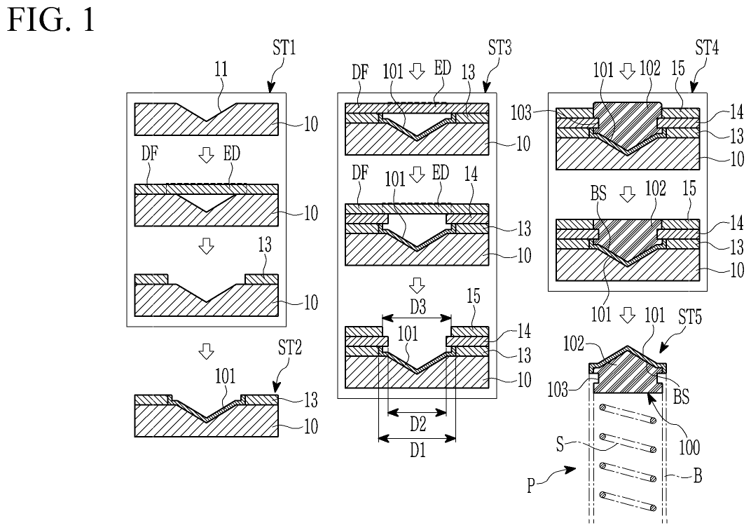

FIG. 1 is a flowchart illustrating cross-sections of a probe member for inspection and a manufacturing method thereof according to a first exemplary embodiment of the present invention. A probe member 100 of the first exemplary embodiment may be coupled to a barrel B to form a pogo pin P in a fifth operation (see ST5). Referring to FIG. 1, a method of manufacturing a probe member for inspection of the first exemplary embodiment includes a first operation ST1, a second operation ST2, a third operation ST3, a fourth operation ST4, and the fifth operation ST5. In the first operation ST1, a first layer mold 13 is formed in a first pattern on an upper surface of the substrate 10, spaced apart from a groove 11 formed on the upper surface of the substrate 10. As an example, the substrate 10 is formed of a silicon wafer. The groove 11 may be formed of a silicon wafer using known techniques.

The first layer mold 13 is formed in the first pattern by stacking a dry film (DF) formed of photoresist on the upper surface of the substrate 10 and performing exposure and development (ED). Although not separately shown, the first layer mold may be formed by applying a photoresist liquid in the first pattern and drying the same.

In the second operation ST2, a contact portion 101 is formed by plating an inner surface of the first layer mold 13 and a surface of the groove 11 with a first metal. The contact portion 101 is a portion that contacts a surface of an object to be inspected, which is an inspection target object, and is formed to be sharp. In the second operation ST2, the contact portion 101 is formed to have a set thickness along the inner surface of the first layer mold 13 and a shape of the groove 11. That is, the contact portion 101 is formed on the surface of the groove 11 and the inner surface of the first layer mold 13. The second operation ST2 does not require flattening the surface of the first layer mold 13 and the surface of the contact portion 101.

In the third operation ST3, a second layer mold 14 is formed in a second pattern on the contact portion 101 and the first layer mold 13, and a third layer mold 15 is formed in a third pattern on the second layer mold 14. The second layer mold 14 is formed in the second pattern by stacking a dry film (DF) formed of photoresist on the contact portion 101 and the first layer mold 13 and performing exposure and development (ED). The third layer mold 15 is formed in the third pattern by stacking a dry film DF formed of photoresist on the second layer mold 14 and performing exposure and development (ED). In the third operation ST3, the dry film (DF) and the second layer mold 14 in the second pattern and the dry film (DF) and the third layer mold 15 in the third pattern may be formed in a continuous process.

In the fourth operation ST4, an internal space of the contact portion 101, the first layer mold 13, the second layer mold 14, and the third layer mold 15 is plated with a second metal to form a boundary surface (BS) along the surface of the contact portion 101 and fill the internal space to form a body portion 102. Since the internal space of the surface of the contact portion 101 is filled with the body portion 102, the area of the boundary surface BS may increase, and accordingly, integral force with the contact portion 101 may increase. Therefore, high durability is achieved at the boundary surface BS between the body portion 102 and the contact portion 101. In addition, in the fourth operation ST4, the body portion 102 is flattened by removing a portion protruding from the surface of the third layer mold 15.

In the third operation ST3, the centers of the first layer mold 13, the second layer mold 14, and the third layer mold 15 are aligned with the center of the contact portion 101, and a second pattern inner diameter D2 of the second layer mold 14 is formed to be less than a first pattern inner diameter D1 of the first layer mold 13 and a third pattern inner diameter D3 of the third layer mold 15.

In the fourth operation ST4, a concave portion 103 is formed on the side of the body portion 102. The dry film DF enables the formation of the second layer mold 14 for forming the concave portion 103. That is, the dry film DF enables the formation of the second layer mold 14 having the smaller second pattern inner diameter D2 on the first layer mold 13 having the first pattern inner diameter D1.

Although not shown separately, the reference numerals of FIG. 1 are referred to. In the fourth operation ST4, a convex portion may be formed in the place of the concave portion 103 on the side of the body portion 102, instead of the concave portion 103. In this case, the first layer mold 13 has the first pattern inner diameter D1, and the second layer mold 14 has the second pattern inner diameter D2 that is larger than the first pattern inner diameter D1.

In the fifth operation ST5, the first layer mold 13, the second layer mold 14, the third layer mold 15, and the substrate 10 are removed to obtain the probe member 100. As an example, the probe member 100 may be mounted in the barrel B of the pogo pin P through the concave groove 103 with the elastic member S. The elastic member S elastically supports the flattened surface of the body portion 102. Although not shown, the probe member may be applied to a location that requires contact with an object for inspection.

In the manufactured probe member 100, the contact portion 101 is formed of a first metal with a sharp point on one side, and the body portion 102 is formed on the other side of the contact portion 101 with a second metal. Since the body portion 102 is formed without flattening the inner surface of the contact portion 101, the integral force with the contact portion 101 increases. Therefore, high durability is achieved at the boundary surface BS between the body portion 102 and the contact portion 101. The body portion 102 allows the probe member 100 to be mounted in the barrel B.

The body portion 102 has the concave portion 103 having a second diameter less than a first diameter of the contact portion 101 formed on the side thereof. The contact portion 101 and the body portion 102 are each formed in separate processes to form the boundary surface BS therebetween. Since the first diameter is the same as the first pattern inner diameter D1, reference numerals are omitted, and since the second diameter is the same as the second pattern inner diameter D2, reference numerals are omitted.

The contact portion 101 forms an internal space connected to a container space having a height of a sharp pyramidal space on the other side. As an example, the pyramidal space is shown as a conic space, but may be formed as a polygonal conic space (not shown). In addition, the container space is shown as a cylindrical space, but may be formed as a polygonal cylinder space (not shown). The contact portion 101 and the body portion 102 form a wide boundary surface BS therebetween along the inner surfaces of the conical space and the cylindrical space.

As such, in the first exemplary embodiment, the probe member 100 for inspection forms one boundary surface BS between the contact portion 101 and the body portion 102, thereby reducing the number of boundary surfaces compared to the related art. The durability of the probe member 100 may be improved by reducing the number of boundary surfaces. Therefore, since the number of boundary surfaces is reduced, there is a low risk of separation from the boundary surface of the probe member 100 during use. Since the number of operations in the manufacturing method is reduced, the resulting costs and time may be reduced.

In the first exemplary embodiment, a set of second and third layer molds 14 and 15 or only one of them may be additionally formed depending on the purpose of the probe member 100, and in this case, a flattening process between the molds may not be required, the contact portion 101 may be filled with a separate material or under a separate condition, and the entire body portion 102 may be filled with the same material or under the same condition.

Hereinafter, various exemplary embodiments of the present invention will be described. Descriptions of the same components as those of the first exemplary embodiment and the previously described exemplary embodiments are omitted, and different components are described.

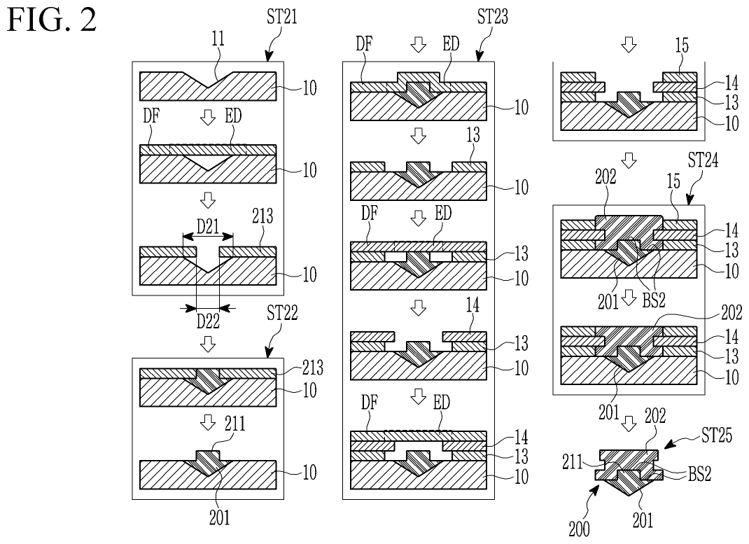

FIG. 2 is a flowchart illustrating cross-sections of a probe member for inspection and a manufacturing method thereof according to a second exemplary embodiment of the present invention. Referring to FIG. 2, the method of manufacturing a probe member for inspection of the second exemplary embodiment includes a first operation ST21, a second operation ST22, a third operation ST23, a fourth operation ST24, and a fifth operation ST25.

In the first operation ST21, a first layer mold 213 is formed on the upper surface of the substrate 10 and further extends to be spaced apart from the groove 11. The dry film DF extends over the groove 11 to enable the formation of the first layer mold 213 for forming a protrusion 211. That is, the dry film DF enables the formation of the first layer mold 213 having an inner diameter D22 less than an inner diameter D21 at the top of the groove 11.

In the second operation ST22, a contact portion 201 filling the lower surface and the inner surface of the first layer mold 213 and the groove 11 and having a protrusion 211 having a width narrower than an upper end of the groove 11 and protruding higher than the upper surface of the substrate 10 is formed, and the first layer mold 213 outside the contact portion 201 is removed to allow the protrusion 211 to protrude from the upper surface of the substrate 10.

In the third operation ST23, the first layer mold 13 is formed again on the upper surface of the substrate 10 to be spaced apart from the protrusion 211, the second layer mold 14 is formed in the second pattern on the protrusion 211 and the first layer mold 13, and the third layer mold 15 is formed in the third pattern on the second layer mold 14.

In the fourth operation ST24, the internal space of the contact portion 201, the protrusion 211, the first layer mold 13, the second layer mold 14, and the third layer mold 15 is plated with a second metal and filled with a boundary surface BS2 along the surface of the contact portion 201 and the protrusion 211 to form a body portion 202.

At this time, the second metal is filled on the upper surface of the substrate 10 and the upper surface of the contact portion 201 and between an inner surface of the first layer mold 13 and an outer surface of the protrusion 211 through an inner surface of the second layer mold 14 and an outer surface of the protrusion 211, and is filled on the inner surfaces of the second and third layer molds 14 and 15 and an upper surface of the protrusion 211 to form the body portion 202.

The boundary surface BS2 forms a structure that implants the contact portion 201 into the body portion 202 through the protrusion 211.

The area of the boundary surface BS2 increases, and as a result, the integral force between the contact portion 201 and the body portion 202 may increase. Therefore, high durability is achieved at the boundary surface BS2 between the body portion 202, the contact portion 201, and the protrusion 211.

In a manufactured probe member 200, the contact portion 201 is filled in the groove 11 and has the protrusion 211 having a narrower width than the upper end of the groove 11 and protruding higher than the upper end of the groove 11. The body portion 202 forms the boundary surface BS2 along the surfaces of the contact portion 201 and the protrusion 211 therebetween.

As such, in the second exemplary embodiment, the probe member 200 for inspection forms one boundary surface BS2 between the contact portion 201, the protrusion 211, and the body portion 202, thereby reducing the number of boundary surfaces compared to the related art. The durability of the probe member 200 may be improved by reducing the number of boundary surfaces. Therefore, since the number of boundary surfaces is reduced, there is a low risk of separation from the boundary surface of the probe member 200 during use. Since the number of operations in the manufacturing method is reduced, the resulting costs and time may be reduced.

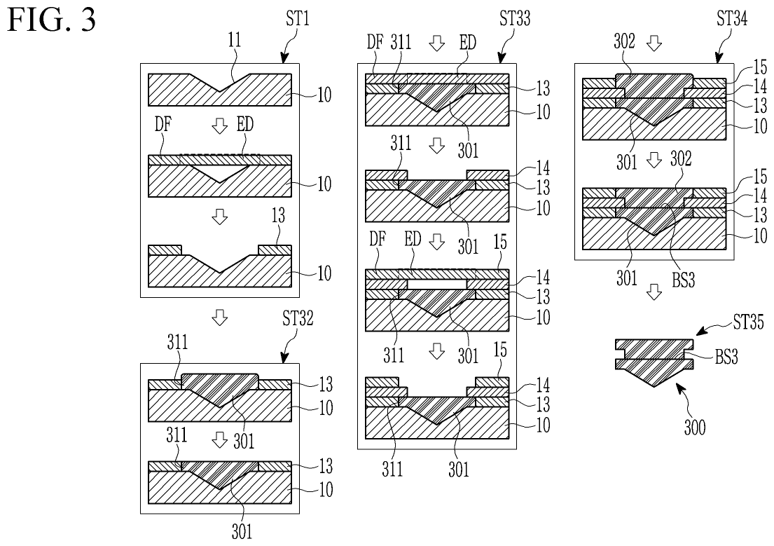

FIG. 3 is a flowchart illustrating cross-sections of a probe member for inspection and a manufacturing method thereof according to a third exemplary embodiment of the present invention. Referring to FIG. 3, the method of manufacturing a probe member for inspection of the third exemplary embodiment includes the first operation ST1, a second operation ST32, a third operation ST33, a fourth operation ST34, and a fifth operation ST35.

In the second operation ST32, a contact portion 301 having an expansion 311 filled in the inner surface of the first layer mold 13 and the groove 11, having a width greater than an upper end of the groove 11 and protruding higher than the upper surface of the substrate 10 is formed. In the second operation ST32, the expansion 311 is flattened by removing the portion protruding from the surface of the first layer mold 13.

In the third operation ST33, the second layer mold 14 in the second pattern is formed on the first layer mold 13 and extends on the expansion 311, and the third layer mold 15 in the third pattern is formed on the second layer mold 14.

In the fourth operation ST34, an internal space of the expansion 311, the second layer mold 14, and the third layer mold 15 is plated with a second metal to form a body portion 302 filling the internal space with a boundary surface BS3 along the surface of the expansion 311.

In a manufactured probe member 300, the contact portion 301 has the expansion 311 filling the groove 11, having a width greater than the upper end of the groove 11 and protruding higher than the upper end of the groove 11.

The expansion 311 and the body portion 302 form the boundary surface BS3 along the surface of the expansion 311 therebetween.

As such, in the third exemplary embodiment, the probe member 300 for inspection forms one boundary surface BS3 between the contact portion 301, the expansion 311, and the body portion 302, so the number of boundary surfaces is reduced compared to the related art.

The durability of the probe member 300 may be improved by reducing the number of boundary surfaces. Therefore, since the number of boundary surfaces is reduced, there is a low risk of separation from the boundary surface of the probe member 300 during use. Since the number of operations in the manufacturing method is reduced, the resulting costs and time may be reduced.

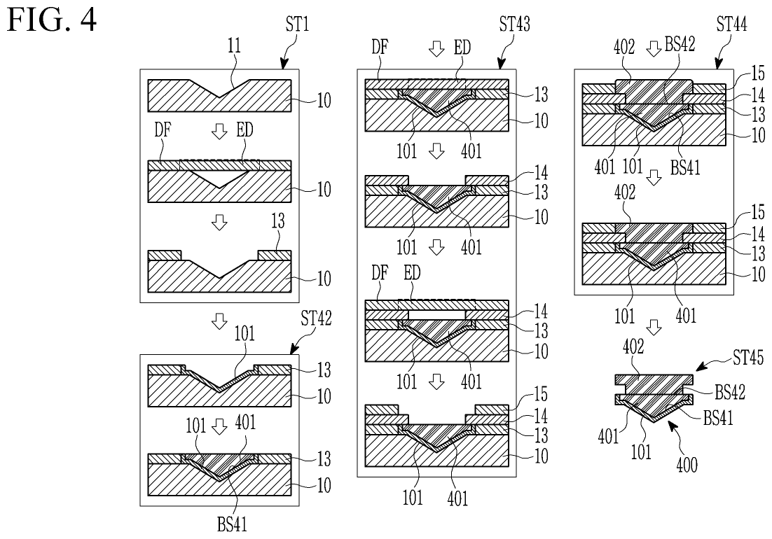

FIG. 4 is a flowchart illustrating cross-sections of a probe member for inspection and a manufacturing method thereof according to a fourth exemplary embodiment of the present invention. Referring to FIG. 4, the method of manufacturing a probe member for inspection of the fourth exemplary embodiment includes the first operation ST1, a second operation ST42, a third operation ST43, a fourth operation ST44, and a fifth operation ST45.

In the second operation ST42, a first boundary surface BS41 is formed along the inner surface of the contact portion 101, and plating is performed with a second metal to a height of the contact portion 101 to be filled to form a first body portion 401.

In the third operation ST43, the second layer mold 14 is formed in the second pattern on the contact portion 101, a first body portion 401, and the first layer mold 13, and the third layer mold 15 in the third pattern is formed on the second layer mold 14. The second layer mold 14 is formed to have the second pattern by stacking a dry film (DF) formed of photoresist on the contact portion 101, the first body portion 401, and the first layer mold 13 and performing exposure and development (ED). The third layer mold 15 is formed in the third pattern by stacking a dry film (DF) formed of photoresist on the second layer mold 14 and performing exposure and development (ED). In the third operation ST43, the dry film (DF) and the second layer mold 14 of the second pattern and the dry film (DF) and the third layer mold 15 of the third pattern may be formed in a continuous process.

In the fourth operation ST44, a second boundary surface BS42 is formed along an upper surface of the first body 401 and plating is formed with a third metal up to a height of the second layer mold 14 and the third layer mold 15 to be filled to form the second body portion 402.

In the fourth operation ST44, an internal space of the contact portion 101, the first body portion 401, the first layer mold 13, the second layer mold 14, and the third layer mold 15 is plated with a third metal to form the second boundary surface BS42 along the surface of the first body portion 401 and filled to form the second body portion 402. The first and second body portions 401 and 402 may be formed by plating with the same metal. Since the second body 402 is filled in the internal space of the surface of the first body 401, the area of the second boundary surface BS42 may increase, and thus, the integral force with the first body 401 may increase. Therefore, high durability is achieved at the second boundary surface BS42 between the second body portion 402 and the first body portion 401. In addition, in the fourth operation ST44, the second body portion 402 is flattened by removing a portion protruding from the surface of the third layer mold 15.

In the fifth operation ST45, the first layer mold 13, the second layer mold 14, the third layer mold 15, and the substrate 10 are removed to obtain a probe member 400.

In the manufactured probe member 400, the contact portion 101 is formed of a first metal with a sharp point on one side, and the body portion includes a first body portion 401 and a second body portion 402 and is formed of second and third metals on the other side of the contact portion 101.

The first body portion 401 forms the first boundary surface BS41 along the inner surface of the contact portion 101 and is formed up to the height of the contact portion 101, and the second body portion 402 forms the second boundary surface BS42 along the upper surface of the first body portion 401.

As such, in the fourth exemplary embodiment, the probe member 400 for inspection forms two first and second boundary surfaces BS41 and BS42 between the contact portion 101 and the first and second body portions 401 and 402, and thus, the number of boundary surfaces is reduced, compared to the related art. When the first and second body portions 401 and 402 are formed of the same metal, only the first boundary surface may be formed and the second boundary surface may not be formed.

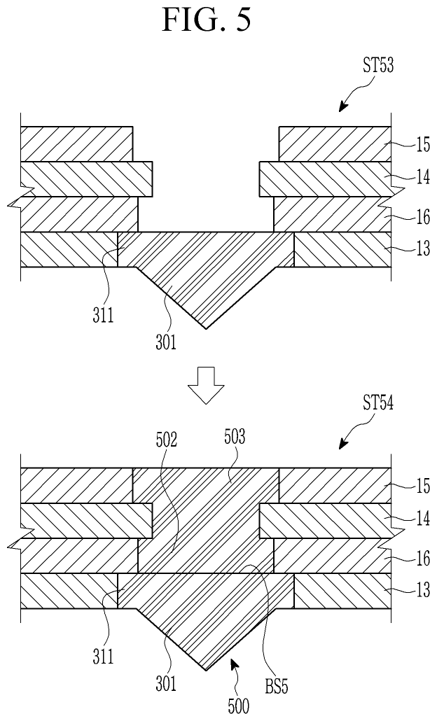

FIG. 5 is a cross-sectional view of a probe member for inspection according to a fifth exemplary embodiment of the present invention. Referring to FIG. 5, in the method of manufacturing a probe member for inspection of the fifth exemplary embodiment, the first and second operations are the same as the first and second operations ST1 and ST32 of the third exemplary embodiment and are therefore omitted.

In the third operation ST53, an additional layer mold 16 in an additional pattern is formed on the first layer mold 13 and extends on the expansion 311, the second layer mold 14 in the second pattern is formed on the additional layer mold 16, and the third layer mold 15 in the third pattern is formed on the second layer mold 14.

In the fourth operation ST54, an internal space of the expansion 311, the additional layer mold 16, the second layer mold 14, and the third layer mold 15 is plated with a second metal to form a body portion 503 filled with a boundary surface BS5 along the surface of the expansion 311 and having an additional layer 502. The additional layer 502 may be formed as a single layer as illustrated or may be formed as multiple layers.

In a manufactured probe member 500, the contact portion 301 is formed by plating to be sharp on one side, and the body portion 503 is formed by plating on the other side of the contact portion 301 and further includes the additional layer 502 on the expansion 311 side.

The additional layer 502 forms a boundary surface BS5 along the inner surface of the expansion 311, and the body portion 503 may be formed in a single process with the additional layer 502. In addition, the body portion may be formed in a separate process from the additional layer and further form a boundary surface.

As such, in the fifth exemplary embodiment, the probe member 500 forms one boundary surface BS5 between the expansion 311 and the additional layer 502, thereby reducing the number of boundary surfaces compared to the related art.

Although not separately shown, the additional layer disclosed in the fifth exemplary embodiment of FIG. 5 may also be appropriately applied to the first exemplary embodiment of FIG. 1, the second exemplary embodiment of FIG. 2, and the fourth exemplary embodiment of FIG. 4.

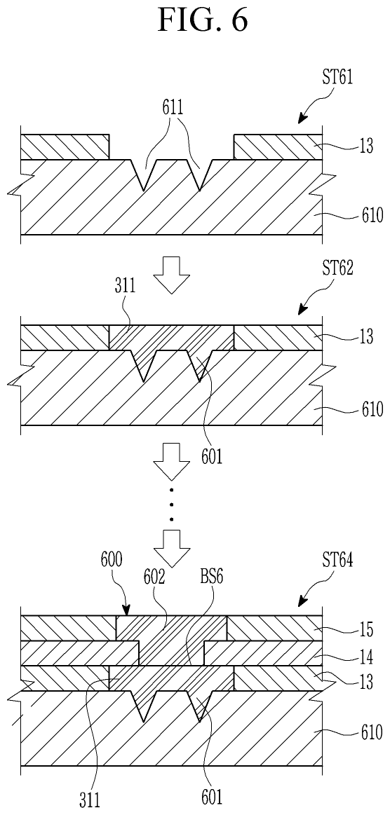

FIG. 6 is a cross-sectional view of a probe member for inspection according to a sixth exemplary embodiment of the present invention. Referring to FIG. 6, in the method of manufacturing a probe member for inspection of the sixth exemplary embodiment, in a first operation ST61, the first layer mold 13 in the first pattern is formed on an upper surface of a substrate 610, spaced apart from a plurality of grooves 611 formed on the upper surface of the substrate 610.

In the second operation ST62, the inner surface of the first layer mold 13 and the groove 611 are plated and filled with the first metal to form a contact portion 601 having the expansion 311 having a wider width than an upper end of the groove 611 and protruding higher than the upper surface of the substrate 610.

In the fourth operation ST64, an internal space of the expansion 311, the second layer mold 14, and the third layer mold 15 is plated with a second metal to form a body portion 602 filled with a boundary surface BS6 along the surface of the expansion 311.

In the manufactured probe member 600, the contact portion 601 is formed in plurality with a sharp point on one side and has the expansion 311 having a wider width than the upper end of the groove 611 and protruding higher than the upper end of the groove 611. The expansion 311 and the body portion 602 form a boundary surface BS6 along the surface of the expansion 311 therebetween.

As such, in the sixth exemplary embodiment, the probe member 600 for inspection forms one boundary surface BS6 between the contact portion 601, the expansion 311, and the body portion 602, so the number of boundary surfaces is reduced compared to the related art. The durability of the probe member 600 may be improved by reducing the number of boundary surfaces.

Although not separately shown, a plurality of contact portions disclosed in the sixth exemplary embodiment may be appropriately applied to the first exemplary embodiment of FIG. 1, the second exemplary embodiment of FIG. 2, the third exemplary embodiment of FIG. 3, the fourth exemplary embodiment of FIG. 4, and the fifth exemplary embodiment of FIG. 5.

Although the exemplary embodiment of the present invention has been described above, the present invention is not limited thereto and may be variously modified within the claim coverage, the description of the invention, and the accompanying drawings, and such modifications also fall within the scope of the present invention.

(Description of reference numerals)

| | |
|---|---|
| 10, 610: substrate | 11, 611: groove |
| 13: first layer mold | 14: second layer mold |
| 15: third layer mold | 16: additional layer mold |
| 100: probe member | 101: contact portion |
| 102: body portion | 103: concave portion |
| 200: probe member | 201: contact portion |
| 202: body portion | 211: protrusion |
| 213: first layer mold | 300: probe member |
| 311: expansion | 401: first body portion |
| 402: second body portion | 500: probe member |
| 502: additional layer | 503: body portion |
| 600: probe member | 601: contact portion |
| 602: body portion | B: barrel |
| BS: boundary surface | BS2: boundary surface |
| BS3: boundary surface | BS41: first boundary surface |
| BS42: second boundary surface | BS5: boundary surface |
| BS6: boundary surface | D1: first pattern inner diameter |
| D2: second pattern inner diameter | D3: third pattern inner diameter |
| D21: upper end inner diameter | D22: inner diameter |
| DF: dry film | P: pogo pin |
| S: elastic member | |

1. A method of manufacturing a probe member for inspection, the method comprising:
a first operation of forming a first layer mold in a first pattern on an upper surface of a substrate to be spaced apart from a groove formed on the upper surface of the substrate;
a second operation of forming a contact portion by plating an inner surface of the first layer mold and a surface of the groove with a first metal;
a third operation of forming a second layer mold in a second pattern on the contact portion and the first layer mold and forming a third layer mold in a third pattern on the second layer mold;
a fourth operation of plating an internal space of the contact portion, the first layer mold, the second layer mold, and the third layer mold with a second metal to be filled with a boundary surface along a surface of the contact portion to form a body portion; and
a fifth operation of removing the first layer mold, the second layer mold, the third layer mold, and the substrate to obtain a probe member.

2. The method of claim 1, wherein:
in the third operation,
centers of the first layer mold, the second layer mold, and the third layer mold are aligned with a center of the contact portion, and
a second pattern inner diameter of the second layer mold is formed to be less than a first pattern inner diameter of the first layer mold and a third pattern inner diameter of the third layer mold, and
in the fourth operation,
a concave portion is formed on a side of the body portion.

3. The method of claim 2, wherein:
in the second operation, the contact portion is formed to have a set thickness along the inner surface of the first layer mold and a shape of the groove.

4. The method of claim 3, wherein:
in the fourth operation, the body portion is formed by forming the boundary surface along an inner surface of the contact portion and filling the internal space.

5. The method of claim 1, wherein:
in the first operation, the first layer mold is formed on the upper surface of the substrate and further extends to be spaced over the groove.

6. The method of claim 5, wherein:
in the second operation,
the contact portion is formed to fill a lower surface and the inner surface of the first layer mold and the groove to have a width narrower than an upper end of the groove and have a protrusion protruding to be higher than an upper surface of the substrate, and
the first layer mold outside the contact portion is removed to allow the protrusion to protrude from the upper surface of the substrate.

7. The method of claim 6, wherein:
in the third operation,
the first layer mold is formed again on the upper surface of the substrate to be spaced apart from the protrusion,
the second layer mold is formed in the second pattern on the protrusion and the first layer mold, and the third layer mold is formed in the third pattern on the second layer mold.

8. The method of claim 7, wherein:
in the fourth operation,
the internal space of the contact portion, the protrusion, the first layer mold, the second layer mold, and the third layer mold is plated with the second metal to form the body portion filling the internal space with the boundary surface along the surface of the contact portion and the protrusion.

9. The method of claim 1, wherein:
in the second operation,
the contact portion filling the inner surface of the first layer mold and the groove to have an expansion having a width greater than an upper end of the groove and protruding to be higher than the upper surface of the substrate is formed.

10. The method of claim 9, wherein:
in the third operation,
the second layer mold is formed in the second pattern on the first layer mold and extends on the expansion, and the third layer mold is formed in the third pattern on the second layer mold, and
in the fourth operation,
the internal space of the expansion, the second layer mold, and the third layer mold is plated with the second metal and filled with a boundary surface along a surface of the expansion to form the body portion.

11. The method of claim 3, wherein:
in the second operation,
a first boundary surface is formed along the inner surface of the contact portion and plating is performed with the second metal up to a height of the contact portion to form a first body portion, and
in the fourth operation,
a second boundary surface is formed along an upper surface of the first body portion and plating is performed with a third metal up to a height of the second layer mold and the third layer mold to form a second body portion.

12. The method of claim 9, wherein:
in the third operation,
an additional layer mold is further formed in an additional pattern on the first layer mold and extends over the expansion,
the second layer mold in the second pattern is formed on the additional layer mold, and
the third layer mold in the third pattern is formed on the second layer mold, and
in the fourth operation,
the internal space of the expansion, the additional layer mold, the second layer mold, and the third layer mold is plated with the second metal and filled with a boundary surface along a surface of the expansion to form a body portion having the additional layer.

13. The method of claim 10, wherein:
in the first operation,
the first layer mold in the first pattern is formed on the upper surface of the substrate and spaced apart from a plurality of grooves formed on the upper surface of the substrate.

14. A probe member for inspection, the probe member comprising:
a contact portion formed of a first metal with a sharp point on one side to contact an object to be inspected; and
a body portion formed of a second metal on the other side of the contact portion,
wherein the body portion includes
a concave portion or a convex portion formed on a side and having a second diameter smaller or greater than a first diameter of the contact portion, and
the contact portion and the body portion
are formed through a separate process to form a boundary surface therebetween.

15. The probe member of claim 14, wherein:
the contact portion forms an internal space connected to a container space having a height of a sharp pyramidal space on the other side, and
the contact portion and the body portion form a boundary surface along inner surfaces of the pyramidal space and the container space therebetween.

16. The probe member of claim 14, wherein:
the contact portion is filled in the groove and has a protrusion having a narrower width than an upper end of the groove and protruding higher than the upper end of the groove, and
the body portion forms a boundary surface along surfaces of the contact portion and the protrusion therebetween.

17. The probe member of claim 14, wherein:
the contact portion is filled in the groove and has an expansion having a wider width than an upper end of the groove and protruding higher than the upper end of the groove, and
the expansion and the body portion form a boundary surface therebetween along the surface of the expansion.

18. The probe member of claim 14, wherein:
the body portion includes a first body portion and a second body portion,
the first body portion forms a first boundary surface along the inner surface of the contact portion and is formed up to a height of the contact portion, and
the second body portion forms a second boundary surface along an upper surface of the first body portion.

19. The probe member of claim 14, wherein:
the body portion further includes an additional layer on the expansion side, and
the additional layer forms a boundary surface along a surface of the expansion therebetween.

20. The probe member of claim 14, wherein:
the contact portion is formed in plurality.
